(19) United States
(12) Patent Application Publication
(10) Pub. No.: US 2013/0228812 A1
(43) Pub. Date: Sep. 5, 2013

(54) LIGHT EMITTING DEVICE AND BACKLIGHT SYSTEM USING THE SAME

(71) Applicant: SHARP KABUSHIKI KAISHA, Osaka (JP)

(72) Inventors: Kazunori ANNEN, Osaka-shi (JP); Makoto IZUMI, Osaka-shi (JP); Tatsuya RYOWA, Osaka-shi (JP); Masato OHNO, Osaka-shi (JP); Kimiko MIEDA, Osaka-shi (JP)

(73) Assignee: SHARP KABUSHIKI KAISHA, Osaka (JP)

(21) Appl. No.: 13/778,281

(22) Filed: Feb. 27, 2013

(30) Foreign Application Priority Data
Mar. 1, 2012 (JP) 2012-045065

(51) Int. Cl. H01L 33/50

(52) U.S. Cl. CPC H01L 33/50
USPC 257/98

(57) ABSTRACT

A light emitting device is provided that includes a light emitting element emitting primary light, and a wavelength conversion portion provided on the light emitting element, absorbing a part of the primary light and emitting secondary light, in which the wavelength conversion portion is made of a plurality of resin layers including at least a first wavelength conversion portion made of a resin layer containing a rare earth-activated phosphor or a transition metal element-activated phosphor, and a second wavelength conversion portion made of a resin layer containing a nanocrystalline phosphor. The first wavelength conversion portion is disposed closer to the light emitting element than the second wavelength conversion portion is.

According to the light emitting device, it becomes possible to prevent a substrate from discoloring due to reaction of a silver part of the light emitting device with a nanocrystalline phosphor, thereby preventing a decrease in light emitting efficiency.

This nonprovisional application is based on Japanese Patent Application No. 2012-045065 filed on Mar. 1, 2012, with the Japan Patent Office, the entire contents of which are hereby incorporated by reference.

### BACKGROUND OF THE INVENTION

1. Field of the Invention

The present invention relates to a light emitting device used in lighting equipment and a display, and particularly to a light emitting device using light directly output from a light source and a phosphor excited by a part of this light output from the light source, and a backlight system using the light emitting device.

2. Description of the Background Art

In recent years, as a light emitting device using a light emitting diode (hereinafter referred to as an LED), an LED backlight for a liquid crystal display and an LED light bulb have received attention. A light emitting portion of the LED backlight and the LED light bulb emits a combination of light obtained as a result of wavelength conversion of a part of light from the LED by a phosphor and light from the LED that is not subjected to wavelength conversion by the phosphor, thereby emitting light different from the original light from the LED.

While a rare earth-activated phosphor has been conventionally mainly used as a phosphor in the above-described light emitting device, attention is recently given to a phosphor formed of a semiconductor nanocrystal (hereinafter referred to as a nanocrystalline phosphor) that allows production of an efficient light emitting device achieving an excellent color rendering property. The semiconductor having a direct transition-type energy gap essentially emits a wavelength inherent in its substance as fluorescence. In this case, by limiting the particle size to approximately the Bohr radius, the kinetic energy that may be exhibited both in the valence band and the conduction electron band is rendered discontinuous, thereby reducing a light emission wavelength in accordance with the particle size. Accordingly, unlike the conventional phosphor, according to the nanocrystalline phosphor, the color of emitted light can be freely controlled from blue (short wavelength) to red (long wavelength) by changing the particle size, and thus, light can be emitted in various desirable spectra. Furthermore, by optimizing the production conditions, variations in particle size distribution of the nanocrystal are eliminated and the nanocrystalline phosphor having a substantially uniform particle size is obtained. As a result, a light emission spectrum with a narrow half band width can be obtained.

Examples of such a nanocrystalline phosphor may include a phosphor having a configuration including a nanocrystal core and a shell layer covering the core, as disclosed in Holger Borchert, et.al., NANO Lett., Vol. 2, and No. 2, 151-154 (2002) (Non-Patent Literature 1). An example of the light emitting device using a nanocrystalline phosphor is disclosed in Japanese Patent Laying-Open No. 2005-285800 (published on Oct. 13, 2005) (Patent Literature 1). FIG. 8 is a schematic side view of a light emitting device 800 shown in this literature. In this light emitting device 800, a silicone resin 804 having nanocrystalline phosphors 803 dispersed therein is applied so as to cover a light emitting element 802 mounted on a substrate 801.

However, the shell layer of the nanocrystalline phosphor disclosed in the above-mentioned literature generally contains S, Se and Te. Furthermore, in the light emitting device, in many cases, silver plating is applied to or silver is contained in a substrate having a light emitting element mounted thereon, an electrode, or a wire through which the light emitting element is connected to the electrode. Silver readily reacts with S, Se and Te. When reaction occurs, silver is colored blackish, with the result that the colored substrate, electrode and wire may absorb the light emitted from the light emitting element and the light emitted from the nanocrystalline phosphor. This leads to a decrease in light emitting efficiency of the light emitting device, which causes a problem. Such a problem may similarly occur also in the case where the core of the nanocrystalline phosphor contains S, Se and Te. Furthermore, the nanocrystalline phosphor is often treated generally in the state where it is contained in a solution such as toluene. In such a solution, S, Se and Te used as a material in the manufacturing process of a nanocrystalline phosphor may be often blended as they are. Accordingly, silver may discolor also in this case, which may negatively affect the light emitting efficiency.

### SUMMARY OF THE INVENTION

The present invention has been made in light of the above-described problems. An object of the present invention is to implement a light emitting device capable of preventing a substrate from discoloring due to reaction of silver parts of this substrate, an electrode and a wire with a nanocrystalline phosphor or a solution containing the nanocrystalline phosphor, thereby preventing a decrease in light emitting efficiency, and a backlight system using this light emitting device.

A light emitting device according to the present invention includes a light emitting element emitting primary light, and a wavelength conversion portion provided on the light emitting element, absorbing a part of the primary light and emitting secondary light, in which the wavelength conversion portion is made of a plurality of resin layers including at least a first wavelength conversion portion made of a resin layer containing a rare earth-activated phosphor or a transition metal element-activated phosphor, and a second wavelength conversion portion made of a resin layer containing a nanocrystalline phosphor. The first wavelength conversion portion is disposed closer to the light emitting element than the second wavelength conversion portion is.

According to the present invention, it becomes possible to implement a light emitting device that can prevent a substrate from discoloring due to reaction of a silver part of the light emitting device with a nanocrystalline phosphor, thereby preventing a decrease in light emitting efficiency.

Furthermore, the light emitting device includes a substrate, an electrode, a light emitting element, and a wire connecting the light emitting element and the electrode. At least one of the substrate, the electrode and the wire is made of a material containing silver. The first wavelength conversion portion contains none of S, Se and Te.

Furthermore, the light emitting device includes a substrate, an electrode, a light emitting element, and a wire connecting the light emitting element and the electrode. The first wavelength conversion portion covers the light emitting element, the substrate, the electrode, and the wire. Furthermore, the plurality of resin layers each emitting the secondary light having a wavelength are arranged, starting from a position close to the light emitting element, in order of the longest wavelength to the shortest wavelength.

A backlight system according to the present invention employs the light emitting device in any of the above description.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a light emitting device according to the first embodiment of the present invention.

FIG. 2 is a diagram showing a manufacturing process of the light emitting device according to the first embodiment.

FIG. 3 is a diagram showing the manufacturing process of the light emitting device according to the first embodiment.

FIG. 4 is a cross-sectional view of a light emitting device according to the second embodiment of the present invention.

FIG. 5 is a cross-sectional view of a light emitting device according to the third embodiment of the present invention.

FIG. 6 is a cross-sectional view of a light emitting device according to the fourth embodiment of the present invention.

FIG. 7 is a cross-sectional view of a backlight system according to the fifth embodiment of the present invention.

FIG. 8 is a cross-sectional view of a conventional light emitting device.

### DESCRIPTION OF THE PREFERRED EMBODIMENTS

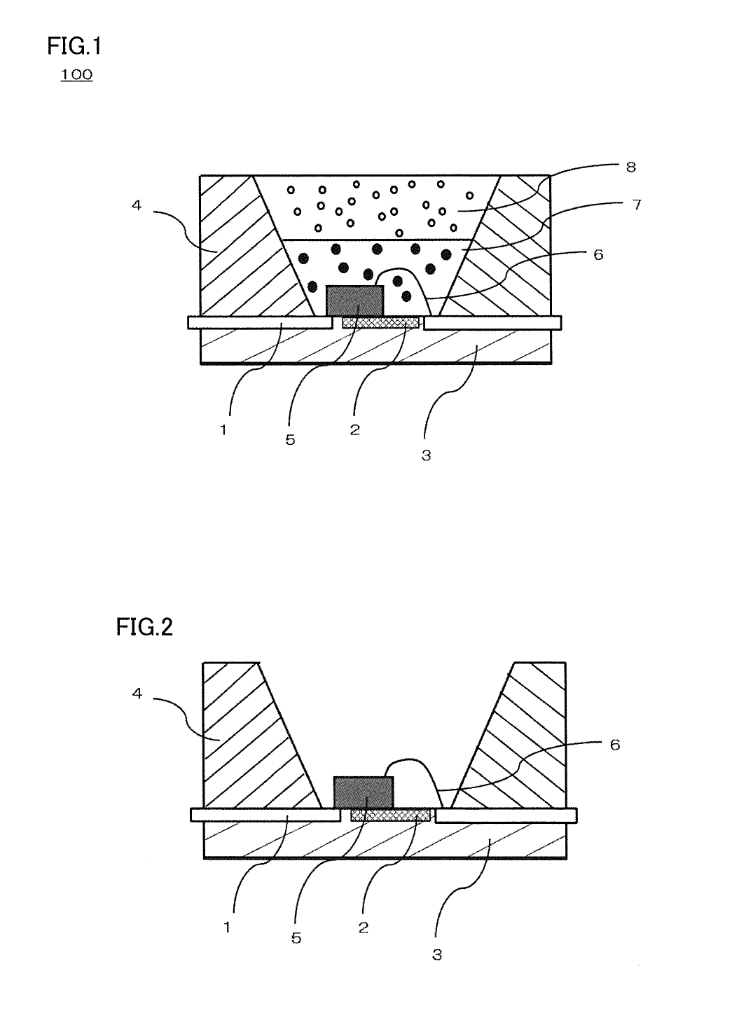

The embodiments of the present invention will be hereinafter described with reference to FIGS. 1 to 7. In the accompanying drawings of the present invention, the same or corresponding components are designated by the same reference characters. In this specification, “nanocrystal” refers to a crystal whose crystal size is decreased to approximately the exciton Bohr radius and in which confinement of an exciton and increase in bandgap due to the quantum size effect are observed.

<First Embodiment>

FIG. 1 is a cross-sectional view of a light emitting device 100 according to the first embodiment of the present invention. Light emitting device 100 is configured to include a substrate 3 having an electrode 1 and a silver plating layer 2 formed therein, a package 4 and a light emitting element 5 provided on electrode 1, a wire 6 connecting light emitting element 5 and electrode 1, a first wavelength conversion portion 7 containing a rare earth-activated phosphor or a transition metal element-activated phosphor, and a second wavelength conversion portion 8 containing a nanocrystalline phosphor, in which first wavelength conversion portion 7 is disposed closer to light emitting element 5 than second wavelength conversion portion 8 is.

A conductor forming electrode 1 functions as an electrically conductive path for electrically connecting light emitting element 5, and is electrically connected to light emitting element 5 by wire 6. A metalized layer containing metal powder such as, for example, W, Mo, Cu or Ag can be used as the conductor. Substrate 3 is required to have a high thermal conductivity and a high reflectivity. Therefore, in addition to a ceramic material such as alumina and aluminum nitride, for example, a resin into which metal oxide fine particles are dispersed is suitably used for substrate 3. The method of connecting light emitting element 5 and electrode 1 may include not only a method of connecting one of a p type electrode and an n type electrode to light emitting element 5 by wire 6 and directly connecting the other of the p type electrode and the n type electrode to the light emitting element as shown in FIG. 1, but also a method of connecting light emitting element 5 to the p type electrode and the n type electrode using two wires 6 for the p type electrode and the n type electrode, respectively.

Package 4 has a high reflectivity and is made of polyphthalamide and the like having excellent adhesion to a sealing resin. Light emitting element 5 is used as a light source and has a peak wavelength preferably in a range from 360 to 470 nm. A GaN-based LED, a ZnO-based LED, a diamond-based LED or the like having a peak wavelength of, for example, 450 nm can be used as light emitting element 5.

As first wavelength conversion portion 7, for example, a rare earth-activated phosphor or a transition metal element-activated phosphor is used. Since these phosphors do not contain S, Se and Te reacting with silver, silver is not colored blackish. Thus, these phosphors are less likely to undergo a decrease in light emitting efficiency by the influence of oxygen or moisture. Examples of a phosphor may include YAG:Ce and the like having a phosphor matrix in which cerium (Ce) is introduced as an activator into yttrium aluminum garnet (YAG).

Furthermore, it is desirable that each of these phosphors is a nitride phosphor that is activated by a rare earth element or a transition metal element. The nitride phosphor has a characteristic of hardly causing a decrease in light emitting efficiency even at a high temperature. Examples of a nitride phosphor may be a sialon phosphor, and there is a known phosphor containing β-type sialon (SiAlON) activated by a rare earth element and a transition metal element. β-type sialon activated by Tb, Yb and Ag becomes a phosphor that emits green light of 525 to 545 nm. Furthermore, a green phosphor is also known that contains β-type sialon activated by Eu²⁺. The Eu-activated β-type sialon phosphor can be produced by the conventionally known method. Specifically, for example, a metal compound containing an optically active element Eu such as Eu₂O₃ and EuN, aluminum nitride (AlN) powder and silicon nitride (Si₃N₄) powder are uniformly mixed and fired at a temperature of approximately 1800 to 2000° C. The mixing ratio of these raw material powders is selected as appropriate in consideration of the composition ratio of the fired phosphors.

An InP-based nanocrystal core can be used as second wavelength conversion portion 8. As for InP, by decreasing a particle size thereof (nanocrystallization), a bandgap can be controlled within the range from blue to red due to the quantum effect. For example, second wavelength conversion portion 8 may be such an element obtained by employing a red phosphor that is an InP-based nanocrystal core having a particle size allowing emission of red light with a wavelength of 620 to 750 nm, and mixing this red phosphor into a silicone resin, and then curing the mixture.

In addition to the above, a red phosphor that is a nanocrystal core formed of the III-V group compound semiconductor other than InP or the II-VI group compound semiconductor may be used as second wavelength conversion portion 8. As for the binary nanocrystalline compound semiconductor formed of the II-VI group compound semiconductor or the III-V group compound semiconductor, for example, the II-VI group compound semiconductor may be CdS, CdSe, CdTe, ZnS, ZnSe, ZnTe, HgS, HgSe, HgTe, PbSe, PbS and the like, and the III-V group compound semiconductor may be GaN, GaP, GaAs, AlN, AlP, AlAs, InN, InP, InAs and the like.

The ternary and quaternary compound semiconductors may include CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, GaNP, GaNAs, GaPAs, AlNP, AlNAs, AlPAs, InNP, InNAs, InPAs, InGaN, GaAlNP, GaAlNAs, GaAlPAs, GaInNP, GaInNAs, GaInPAs, InAlNP, InAlNAs, InAlPAs and the like.

Among others, a nanocrystal core containing In and P or a nanocrystal core containing Cd and Se is preferably used as second wavelength conversion portion 8.

This is because the nanocrystal core containing In and P or the nanocrystal core containing Cd and Se is readily produced to have a particle size that allows light emission in the visible light range (380 nm to 780 nm).

Among them, InP or CdSe is particularly preferably used. This is because the number of materials forming each of InP and CdSe is small and fabrication is easy. In addition, InP and CdSe are materials showing a high quantum yield and showing high light emission efficiency when InP and CdSe are irradiated with the light from the LED. The quantum yield herein refers to a ratio of the number of photons emitted as fluorescence to the number of photons absorbed.

Further, InP that does not contain highly toxic Cd is preferably used as second wavelength conversion portion 8.

Furthermore, ZnS can be used for the shell layer that covers a nanocrystal core. ZnS shows excellent lattice matching to InP. Accordingly, if the thickness of the shell layer is increased, the shell layer does not peel off from the surface of the nanocrystal core. Therefore, the shell can protect a defective part of the nanocrystal core surface while an effect of confining electrons is improved, thereby allowing an increase in light emitting efficiency of the InP nanocrystal core.

In addition, a II-VI group compound semiconductor other than ZnS or a III-V group compound semiconductor can be used as a composition of the semiconductor forming the shell layer. For example, GaAs, GaP, GaN, GaSb, InAs, InSb, AlAs, AlP, AlSb, AlN, ZnO, ZnSe, ZnTe, and the like may be used.

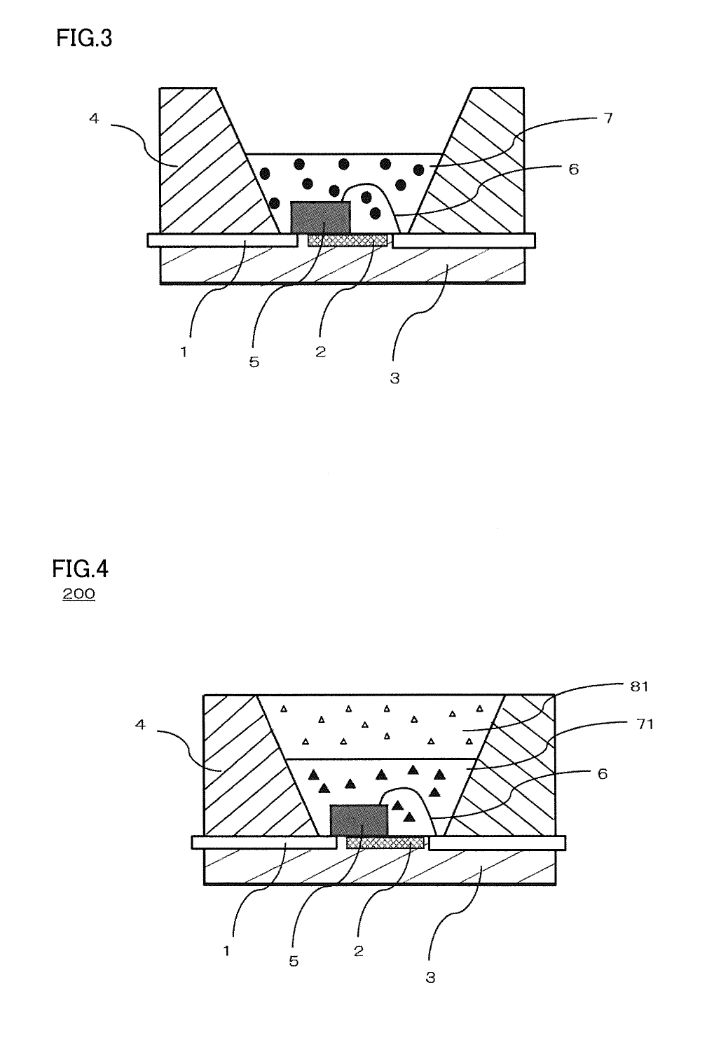

Then, an example of a method of manufacturing light emitting device 100 will be hereinafter described. FIGS. 2 and 3 each illustrate a process of manufacturing light emitting device 100. First, as shown in FIG. 2, an LED package including electrode 1, silver plating layer 2, substrate 3, package 4, light emitting element 5, and wire 6 is prepared.

Then, silicone resin and Eu-activated β-type sialon phosphor are mixed in a ratio of 1000:200 in terms of ratio by weight. SCR1011 manufactured by Shin-Etsu Chemical Co., Ltd. is used as silicone resin. Resins other than SCR1011 can also be used as long as they allow Eu-activated β-type sialon phosphors to be uniformly dispersed therein and are transparent and resistant to heat and light. Then, as shown in FIG. 3, the resin containing Eu-activated β-type sialon phosphors is put by drops into the LED package so as to entirely cover wire 6, and then cured for a prescribed time period, thereby fabricating first wavelength conversion portion 7.

Then, a resin and a toluene solution containing a red phosphor formed of a nanocrystal (hereinafter referred to as a red nanocrystalline phosphor) are mixed such that a ratio between the resin and the red nanocrystalline phosphor is 1000:4.62 in terms of ratio by weight. A phosphor formed of an InP crystal is used as the red nanocrystalline phosphor. In addition, SCR1011 manufactured by Shin-Etsu Chemical Co., Ltd. is used as silicone resin. Resins other than SCR1011 can also be used as long as they allow the red nanocrystalline phosphors to be uniformly dispersed therein and are transparent and resistant to heat and light.

Then, the resin containing red nanocrystalline phosphors is put by drops into the LED package having first wavelength conversion portion 7 formed therein, and then cured for a prescribed time period, thereby fabricating second wavelength conversion portion 8. Although the thickness of each of first wavelength conversion portion 7 and second wavelength conversion portion 8 in the light path direction of the primary light is set to be the same in this case, the thickness may be set as appropriate depending on the desired color balance. Light emitting device 100 shown in FIG. 1 is fabricated in the manner as described above. The manufacturing method is not limited to the above-described method as long as second wavelength conversion portion 8 is formed on first wavelength conversion portion 7.

Since a compound containing 5, Se and Te is included in the red nanocrystalline phosphor and toluene containing this red nanocrystalline phosphor, this compound reacts with silver and the reacted portion is colored blackish. According to the present embodiment, however, since the Eu-activated β-type sialon phosphor that does not react with silver is contained, silver does not discolor, which thereby prevents such a disadvantage that the discolored silver absorbs light emitted from light emitting element 5 or light emitted as fluorescence. Therefore, the brightness of light emitting device 100 can be maintained. Furthermore, the Eu-activated β-type sialon phosphor has a relatively narrow spectrum that less overlaps with a red spectrum of the nanocrystalline phosphor, thereby producing an effect of improving the color purity. <Second Embodiment>

Then, the second embodiment will be hereinafter described. The present embodiment is different from the first embodiment in that a CaAlSiN₃ red phosphor (which will be hereinafter referred to as CASN) is used for the first wavelength conversion portion and a green nanocrystalline phosphor (for example, InP (core)/ZnS (shell)) is used for the second wavelength conversion portion.

FIG. 4 is a cross-sectional view of a light emitting device 200 according to the second embodiment of the present invention. A resin layer containing a green nanocrystalline phosphor as a second wavelength conversion portion 81 is formed on a resin layer containing CASN as a first wavelength conversion portion 71. CASN is resistant to heat, and further, does not contain S, Se and Te reacting with silver, and therefore, silver is not colored blackish.

Furthermore, a phosphor absorbs light having energy greater than the excitation energy and emits secondary light as fluorescence. Since the secondary light emitted by a phosphor with large excitation energy such as, for example, a green phosphor is absorbed by a phosphor with small excitation energy such as, for example, a red phosphor, it is difficult to obtain a desired color balance. Therefore, by arranging the phosphor having a longer peak wavelength on the side close to light emitting element 5 that emits the primary light as in the present embodiment, the secondary light emitted by each phosphor is hardly absorbed again by the phosphors that emit other colors, so that a light emitting device achieving an excellent color balance can be readily obtained.

<Third Embodiment>

Then, the third embodiment will be hereinafter described. The present embodiment is different from any of the above-described embodiments in that a wavelength conversion portion is formed of three layers.

FIG. 5 is a cross-sectional view of a light emitting device 300 according to the third embodiment of the present invention. A resin layer containing a red nanocrystalline phosphor (for example, InP (core)/ZnS (shell)) as a second wavelength conversion portion 82 is formed on a resin layer containing CASN as a first wavelength conversion portion 72. Also, a resin layer containing a green nanocrystalline phosphor (for example, InP (core)/ZnS (shell)) as a third wavelength conversion portion 92 is formed on second wavelength conversion portion 82.

By arranging CASN on the side close to light emitting element 5 as in the present embodiment, the nanocrystalline phosphor does not react with silver and not cause discoloration, and also, a narrow light emission spectrum can be achieved by the red nanocrystalline phosphor. Consequently, a light emitting device achieving an excellent color balance can be readily obtained.

<Fourth Embodiment>

Then, the fourth embodiment will be hereinafter described. The present embodiment is different from any of the above-described embodiments in that the wavelength conversion portion is formed of three layers and each wavelength conversion portion emits secondary light of a different color.

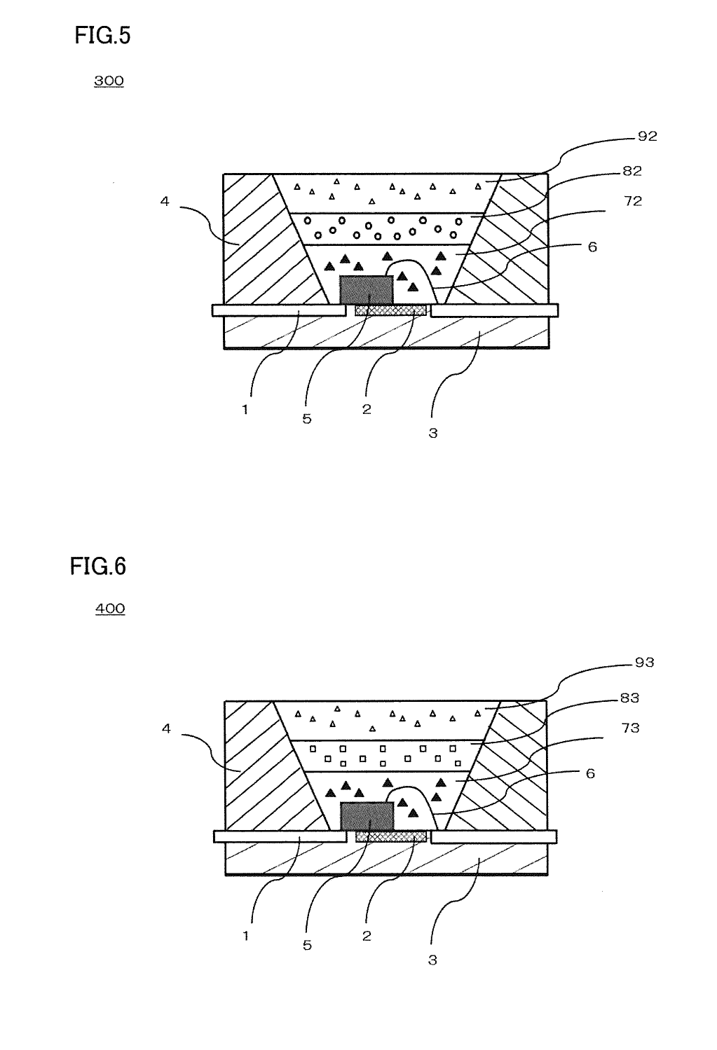

FIG. 6 is a cross-sectional view of a light emitting device 400 according to the fourth embodiment of the present invention. A resin layer containing a yellow nanocrystalline phosphor (for example, InP (core)/ZnS (shell)) as a second wavelength conversion portion 83 is formed on a resin layer containing CASN as a first wavelength conversion portion 73. Also, a resin layer containing a green nanocrystalline phosphor (for example, InP (core)/ZnS (shell)) as a third wavelength conversion portion 93 is formed on second wavelength conversion portion 83.

As in the present embodiment, by arranging CASN on the side closer to light emitting element 5, the nanocrystalline phosphor does not react with silver and not cause discoloration, and by arranging the phosphor having a longer peak wavelength on the side closer to light emitting element 5 that emits primary light, the secondary light emitted by each phosphor is hardly absorbed again by the phosphors that emit other colors. Consequently, a light emitting device achieving an excellent color balance can be readily obtained.

<Fifth Embodiment>

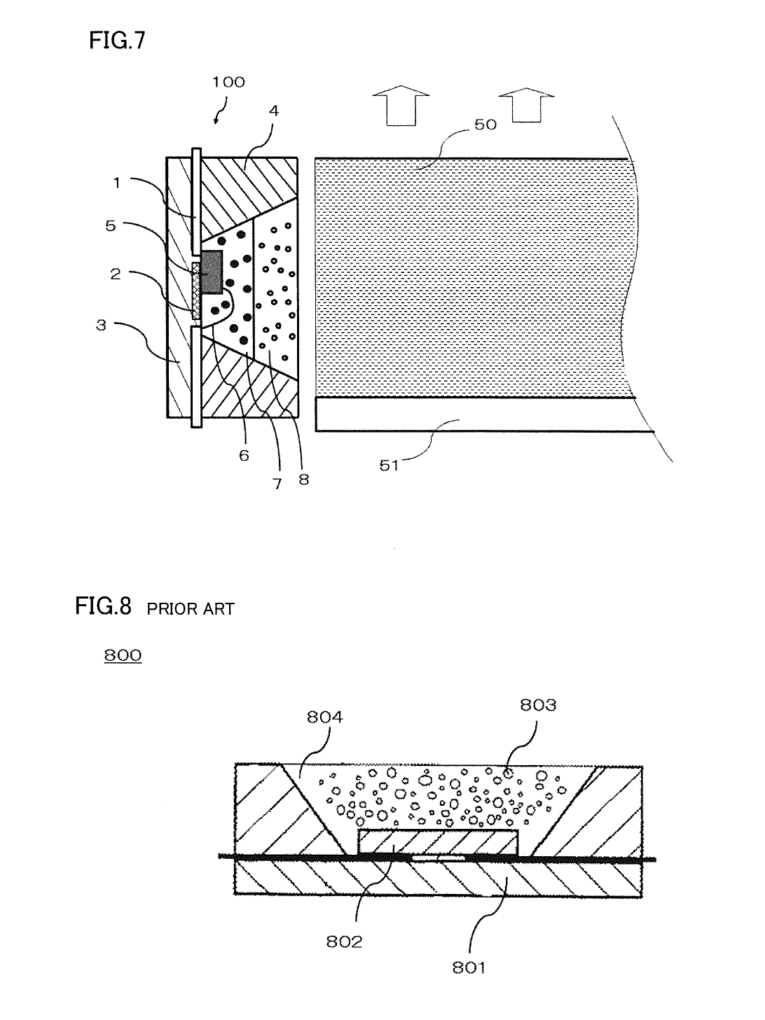

Then, a side-edge type backlight system according to the present invention will be described with reference to FIG. 7. The side-edge type backlight system in the present embodiment includes a light emitting device 100, a light guide plate 50 and a reflective plate 51. In the present embodiment, the primary light and the secondary light output from light emitting device 100 go into light guide plate 50, and are reflected by reflective plate 51, to thereby extract the primary light and the secondary light from the surface opposed to reflective plate 51.

Since light emitting device 100 is configured such that an Eu-activated β-type sialon phosphor layer not reacting with silver is stacked on light emitting element 5 on which a red nanocrystalline phosphor is stacked, silver does not discolor. Accordingly, silver does not absorb light emitted from light emitting element 5 or light emitted as fluorescence, so that the brightness of light emitting device 100 can be maintained. Therefore, for example, when the present embodiment is applied to a backlight system of a television set, the television brightness can be maintained while a decrease in light emitting efficiency can be prevented.

Although the present embodiment has presented the example in which a lighting device of the present invention is employed for a side-edge type backlight, the lighting device of the present invention can also be used, for example, as a direct backlight. Although light emitting device 100 has been used in the present embodiment, any light emitting device described in the above embodiments may be used.

As described in each of the above embodiments, by arranging a phosphor layer not reacting with silver between a nanocrystalline phosphor and a light emitting element, it becomes possible to implement a light emitting device capable of preventing a substrate from discoloring due to reaction of a silver part of the substrate with a nanocrystalline phosphor, thereby preventing a decrease in light emitting efficiency.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A light emitting device comprising:
a light emitting element emitting primary light; and
a wavelength conversion portion provided on said light emitting element, absorbing a part of said primary light and emitting secondary light, wherein
said wavelength conversion portion is made of a plurality of resin layers including at least
a first wavelength conversion portion made of a resin layer containing a rare earth-activated phosphor or a transition metal element-activated phosphor, and
a second wavelength conversion portion made of a resin layer containing a nanocrystalline phosphor, and
said first wavelength conversion portion is disposed closer to said light emitting element than said second wavelength conversion portion is.

2. The light emitting device according to claim 1, wherein said light emitting device includes a substrate, an electrode, a light emitting element, and a wire connecting said light emitting element and said electrode, and at least one of said substrate, said electrode and said wire is made of a material containing silver.

3. The light emitting device according to claim 1, wherein said first wavelength conversion portion contains none of S, Se and Te.

4. The light emitting device according to claim 1, wherein said light emitting device includes a substrate, an electrode, a light emitting element, and a wire connecting said light emitting element and said electrode, and said first wavelength conversion portion covers said light emitting element, said substrate, said electrode, and said wire.

5. The light emitting device according to claim 1, wherein said plurality of resin layers each emitting the secondary light having a wavelength are arranged, starting from a position close to said light emitting element, in order of the longest wavelength to the shortest wavelength.

6. A backlight system using the light emitting device according to claim
